(19) United States
(12) Patent Application Publication
(10) Pub. No.: US 2007/0099359 A1
(43) Pub. Date: May 3, 2007

(54) Carrier multiplication in quantum-confined semiconductor materials

(76) Inventors: Victor I. Klimov, Los Alamos, NM (US); Richard D. Schaller, Santa Fe, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(21) Appl. No.: 11/404,467

(22) Filed: Apr. 13, 2006

Related U.S. Application Data
(60) Provisional application No. 60/670,726, filed on Apr. 13, 2005.

(51) Int. Cl. H01L 21/338

(52) U.S. Cl. 438/183

(57) ABSTRACT

The present invention is directed to processes and devices for carrier multiplication using nanosized quantum confined semiconductor materials such as semiconductor nanocrystals.

### RELATED APPLICATIONS

This application claims the benefit of Ser. No. 60/670,726 filed Apr. 13, 2005.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates to processes and devices for carrier multiplication using quantum confined semiconductor materials such as semiconductor nanocrystals. The present invention further relates to devices employing carrier multiplication from quantum confined semiconductor materials.

### BACKGROUND OF THE INVENTION

Solar power is an important source of clean, renewable energy. The maximum calculated thermodynamic conversion efficiency in solar cells is 43.9% under concentrated solar illumination. This calculation is based upon the assumption that absorption of an individual photon with energy above a semiconductor band gap (E_{g}) results in the formation of a single exciton (electron-hole pair) and that all photon energy in excess of E_{g} is lost through electron-phonon interactions. Overcoming this apparent thermodynamic limit has been greatly desired and sought.

Several methods have been offered to increase the power conversion efficiency of solar cells including the development of tandem cells, impurity band and intermediate band devices, hot electron extraction, and carrier multiplication. Carrier multiplication, which was first observed in bulk semiconductors in the 1950s, would provide increased power conversion efficiency in the form of increased solar cell photocurrent.

The concept of carrier multiplication using nanosize semiconductor crystals was previously proposed by Nozik, Physica E, vol. 14, pp. 115-120 (2002), but there had been no successful demonstration of this concept.

It is an object of the present invention to attain carrier multiplication in quantum confined semiconductor materials as numerous applications can be achieved with such a result.

### SUMMARY OF THE INVENTION

In accordance with the purposes of the present invention, as embodied and broadly described herein, the present invention provides a process of converting light into charge carriers including irradiating nanosized quantum confined semiconductor materials with light of sufficient energy to yield carrier multiplication whereby greater than one electron-hole pair is generated per single absorbed photon from said light.

The present invention still further provides a photovoltaic cell for converting light into charge carriers including an anode and a cathode wherein at least one either the anode and cathode is transparent, a layer of semiconductor nanocrystals disposed on one of the anode and cathode, the layer of semiconductor nanocrystals capable of yielding carrier multiplication upon exposure to light of sufficient energy whereby greater than one electron-hole pair is generated per single absorbed photon from said light, and, a current collection element wherein the current collection element is electrically connected to the anode or cathode, so as to remove charge carriers from the cell.

The present invention still further provides a process of converting a high energy carrier into additional charge carriers including contacting nanosized quantum confined semiconductor materials with high energy carriers to yield carrier multiplication whereby greater than one electron-hole pair is generated per single high energy carrier.

The present invention still further provides a process of converting a high energy particle into multiple charge carriers including contacting nanosized quantum confined semiconductor materials with high energy particles to yield carrier multiplication whereby greater than one electron-hole pair is generated per single high energy particle. The high energy particles can be, e.g., alpha particles, beta particles, gamma particles or x-rays.

### BRIEF DESCRIPTION OF THE DRAWINGS

FIG. 1(a) shows in the absence of impact ionization, a carrier, in this case an electron (filled circle) with energy in excess of the semiconductor band gap (E_{g}) is lost as heat as the carrier relaxes to the conduction band edge (labeled c, while the valence band is labeled v).

FIG. 1(b) shows that with carrier multiplication, a carrier, in this case an electron, having at least two times the energy of the band gap (labeled E_{g}) of the semiconductive material it is located in, can relax to a lower energy state (still in the conduction band) via transfer of at least an energy E_{g} to a valence band electron. Thus, this process creates, in this case, three carriers [two electrons and a hole (empty circle)] from one initial carrier. This process can work equivalently with holes as the high-energy carrier.

FIG. 2(a) shows carrier multiplication is inefficient in bulk semiconductors. Both the energy and momentum of carriers must be conserved through the impact ionization process. Energy can easily be conserved in the process of impact ionization in bulk materials, however, momentum, which is related to energy in bulk materials is not easily conserved, which makes this process very inefficient.

FIG. 2(b) shows that in quantum-confined materials, impact ionization can be highly efficient because the energy and momentum are no longer directly related, which makes the momentum conservation requirement that restricts the process in bulk materials not prevent the process from occurring. In this figure, electrons are shown as filled-in circles and holes are shown as empty circles. The processes shown in parts A and B of this figure can take place with either the electron or the hole as the initial, highly-excited carrier.

FIG. 3(a) shows carrier multiplication enhanced photovoltaic designs and principles of operation. The simplest photovoltaic design that can benefit from quantum-confinement enhanced carrier multiplication is a sandwich structure consisting of at least a transparent electrode, a quantum-confined semiconductor material, and a second electrode. The transparent electrode can be a metal oxide such as indium-tin-oxide that may be coated with other conducting layers (such as, e.g., poly(styrene sulfonate) and/or poly(3,4-ethylenedioxythiophene)), or a transparent metal film (such as gold, aluminum or platinum) deposited on a transparent substrate upon which a quantum-confined semiconductor material is deposited (e.g., by spin-casting), or produced upon the electrode in situ. The back electrode can be selected purely based upon its work function and mobility properties. More complex improvements on this design would involve use of high surface area electrodes (inter-digitated, roughened, etc.), introduction of small molecules to promote rapid charge transfer (CT), and/or heterostructuring of the semiconductor material to promote rapid charge transfer.

FIG. 3(b) shows a photovoltaic cell in which a quantum-confined semiconductor material is used to sensitize and produce enhanced photocurrent via charge transfer to p- and n-doped regions of a pn junction solar cell consisting of bulk Si, bulk Ge, bulk SiGe, bulk GaAs, bulk CdTe, bulk CuInSe₂, bulk TiO₂, bulk GaN, bulk AIN, and/or bulk InN. When photons are absorbed by a thin layer of quantum-confined semiconductor material, multiexcitons are generated that charge transfer to the p- and n-doped bulk semiconductor material.

FIG. 3(c) shows charge transfer of an electron and hole out of the quantum-confined semiconductor material that originally contained a biexciton (or multiexciton) leaves the quantum-confined material with a single exciton that is long-lived (tens to thousands of nanoseconds) which eventually also undergoes charge transfer to produce enhanced photocurrent.

FIG. 3(d) shows energy transfer of an entire exciton from a quantum-confined semiconductor that has a multiexciton can occur between spatially-separated, quantum-confined semiconductors. Energy transfer of an exciton can also occur between the quantum-confined semiconductor material and bulk semiconductor material.

FIG. 4(a) shows photo-excitation at 1.55 eV produces a change of absorption (Δα) at the A₁ absorption maximum (here 0.86 eV) that is linear up to Nₑₕ≈3.

FIG. 4(b) shows carrier relaxation dynamics monitored at the A₁ absorption feature (0.86 eV) using 1.55 eV photo-excitation, for which impact ionization cannot occur. At Nₑₕ=0.6 (line 42), primarily slow relaxation dynamics are observed at Nₑₕ=1.6 (line 44), Δα becomes larger and a fast relaxation component becomes well pronounced; this component (shown in the inset after isolation from the slow component) corresponds to rapid Auger recombination.

FIG. 4(c) shows the lifetime of the fast relaxation component depends linearly upon the NC volume (squares 46), which is indicative of Auger recombination of biexcitons.

FIG. 4(d) shows a transient absorption (TA) trace recorded with Nₑₕ=0.25 using 3.10 eV pump photon energy (blue line), for which impact ionization is possible, shows a fast, “biexcitonic” relaxation component when monitoring the A₁ absorption feature. The extracted fast component (inset) is nearly identical to the inset shown in panel (b). For comparison, a trace of single exciton relaxation dynamics recorded using 1.55 eV photo-excitation with Nₑₕ=0.6 has been replotted from panel (a) (line 48). The NC-volume dependence of the biexciton lifetime observed in the impact ionization regime (circles in panel (c)) closely agrees with the biexciton lifetimes measured using 1.55 eV excitation (squares in panel 1(c)).

FIGS. 5(a)-5(c) show the A₁ feature relaxation dynamics, normalized at long time delay, measured for PbSe NCs having three different values of E_{g} are shown using photo-excitation at 3.10 (line 52) and 1.55 eV (line 54) with Nₑₕ<0.5. These studies show that impact ionization efficiency is dependent upon the photo-generated exciton excess energy. The inset in panel (b) shows the measurable build-up of the TA signal for a 3.10 eV excitation (line 56) and an autocorrelation of the pump pulse (line 58).

FIG. 5(d) shows impact ionization efficiencies as a function of pump photon energy are compared for two cases: 1) the pump photon energy was fixed and E_{g} of the NCs was changed (black squares), and 2) E_{g} was fixed and the pump photon energy was changed (circles).

FIG. 5(e) shows for a fixed NC energy gap (E_{g}=0.94 eV), a tunable pump laser source was used to vary the pump photon energy and the efficiency of impact ionization was measured. All traces were normalized at long delay.

### DETAILED DESCRIPTION

The present invention is concerned with carrier multiplication through impact ionization in quantum-confined semiconductor materials. In the process and devices of the present invention, carrier multiplication from impact ionization can result in significant increase in the carrier to photon ratio.

The term “quantum confinement” relates to where the size of a nanosized particle or nanoparticle is smaller than or comparable in size to the Bohr radius of the exciton. Nanoparticles (if crystalline generally called nanocrystals) exhibiting quantum confinement effects are often called quantum dots (QDs) if essentially dot-shaped, or quantum rods if essentially rod-shaped.

This invention describes a method of efficient carrier generation via carrier multiplication (producing additional carriers in semiconductor materials from initially generated, high-energy carriers). Carrier multiplication becomes highly efficient when carriers in a semiconductor material feel the effects of quantum-confinement (which occurs when a semiconductor material is made very small). This effect of carrier multiplication is efficient in quantum-confined materials for physical reasons that are unique to such materials (carrier multiplication is very inefficient in bulk semiconductor materials). Efficient carrier multiplication in quantum-confined materials should affect many technologies from photovoltaics and photodiodes to efficient optical switches and optical amplifiers, each of which can benefit from the generation of carriers. The carrier multiplication can arise from contacting the quantum-confined semiconductor material with a photon with suitable energy, a high energy charge carrier (either an electron or a hole) or a high energy particle (an alpha particle, a beta particle, a gamma particle or an x-ray).

Impact ionization is an Auger-type process whereby a high-energy exciton, created in a semiconductor by absorbing a photon of energy 2E_{g}, relaxes to the band edge via energy transfer of at least 1E_{g}, to a valence band electron, which is excited above the energy gap. The result of this energy transfer process is that two or more excitons can be formed for one absorbed photon. Thus, this process converts more of the high photon energy portion of the solar spectrum into usable energy. Thus the energy necessary for the nanosized quantum confined semiconductor materials to yield carrier multiplication is related to the band gap. The suitable energy also is related to the effective masses of the semiconductor materials.

As used herein, the term “nanocrystal” refers to particles less than about 500 Angstroms in the largest axis, and preferably from about 300 to about 500 Angstroms. Also, within a particularly selected colloidal nanocrystal, the colloidal nanocrystals can be substantially monodisperse, i.e., the particles have substantially identical size and shape, but such monodispersity is generally not required in the present invention. In some instances, the nanosized quantum confined semiconductor materials may be amorphous in the present invention. In some instances, the nanosized quantum confined semiconductor materials may be nanoporous materials such as nanoporous silicon and the like.

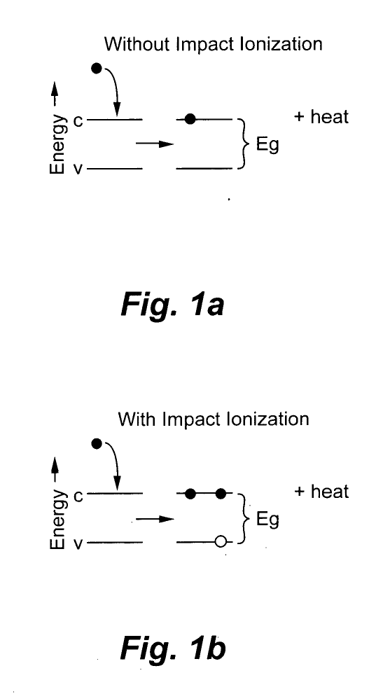

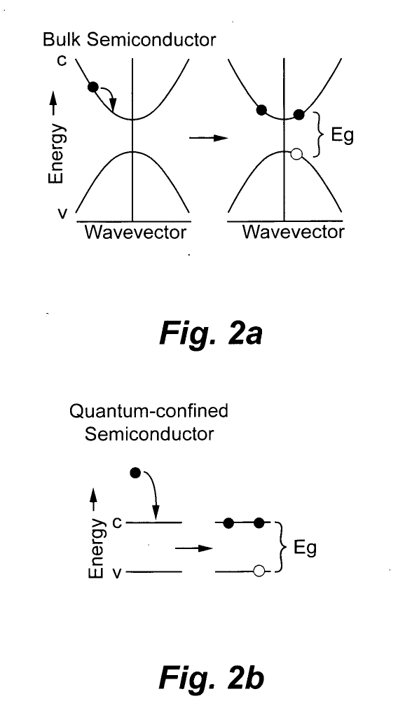

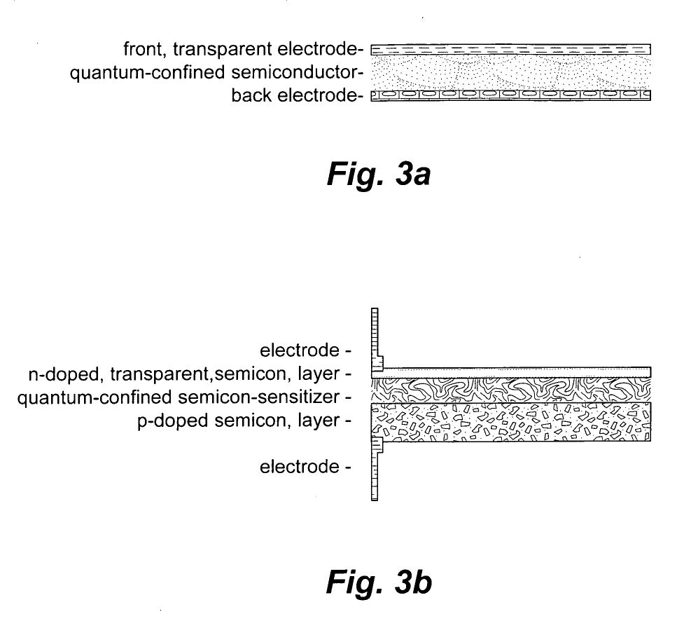

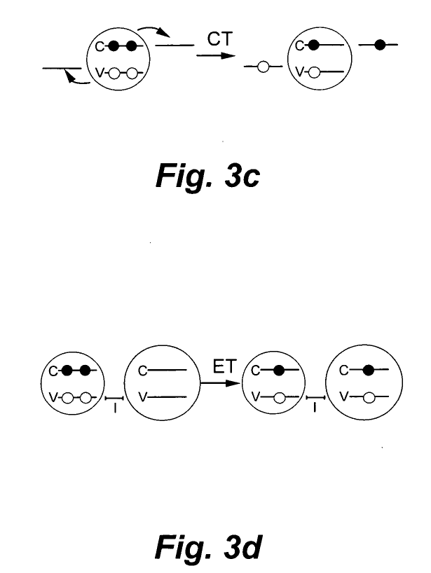

Carrier multiplication is an energy-conserving process in which a high-energy carrier (high-energy meaning that the carrier has energy in excess of the material band gap) in a semiconductive material (which can be either an electron or a hole) relaxes to a lower-energy state in the conduction band via transfer of an amount of energy to a valence band electron, which is excited into the conduction band (see FIG. 1). Thus, this process causes a single high-energy carrier to multiply into two or more lower-energy carriers.

Thus, impact ionization causes additional carriers to be produced subsequent to the generation of a high-energy single carrier. The carrier undergoing impact ionization can also be part of an electron-hole pair (generally referred to as an “exciton”). Many devices can benefit significantly from the generation of multiple carriers. In the absence of this process, carrier energy that is in excess of the band gap is dissipated as heat.

Both the energy and momentum of carriers must be conserved in the process of impact ionization. In bulk materials, impact ionization has been found to be inefficient. This low efficiency stems from the fact that the energy of a carrier and its momentum are related in bulk semiconductors. At high energy, a carrier in a bulk semiconductor necessarily has high momentum. In the process of impact ionization, energy is conserved as the high-energy carrier transfers energy to generated carriers. However, each carrier has low energy and low momentum following the impact ionization process. Thus, momentum is not conserved, and so the process is inefficient. However, when a semiconductive material is made very small (on the nanometer scale), carriers experience quantum-confinement effects that give rise to discrete, “atomic-like” energy levels; this is in place of the band structure that exists in bulk materials. In quantum-confined systems, a high-energy carrier is not required to have a high translational momentum. Thus, the momentum conservation requirement that hinders impact ionization efficiency in bulk materials does not hinder the impact ionization process in quantum-confined materials.

Quantum-confinement enhanced carrier multiplication can be beneficial to any optical or electronic device application that benefits from the efficient production of carriers. Either carrier (electron or hole) can undergo carrier multiplication as long as it has at least one band gap of excess energy, and the high-energy carrier can be generated optically, electrically, or via high-energy particles. The application of quantum-confinement enhanced carrier multiplication to devices such as optical switches works with the existing optical switch design geometries except that excitation of the switch should be performed with high photon-energies. The same is true for optical amplifiers, for which quantum-confinement enhanced carrier multiplication can cause population inversion via a linear absorption event for a two-fold degenerate material. Carrier multiplication can reduce gain and lasing thresholds by using a blue excitation pulse, or by using high voltage electrical injection.

Quantum-confinement enhanced carrier multiplication is a process that can improve the power conversion efficiency of photovoltaic devices via an increased photocurrent for a fixed photovoltage. In these devices optical excitation of the quantum-confined semiconductor material via solar photons will ultimately result in the formation of biexcitons (a biexciton is a pair of excitons) (and multiexcitons such as triexcitons, etc.) when impact ionization is operational. In order to benefit from the production of biexcitons (and/or multiexcitons) the biexciton must be dissociated before the process of Auger recombination causes relaxation of the biexciton into highly excited single excitons (the inverse of carrier multiplication). For many materials, this process is known to take place on the tens to hundreds of picosecond timescale (see, e.g., Klimov et al., Science, 2000, 287, 1011 and Schaller et al., J. Phys. Chem. B, 2003, 107, 13765). Thus, dissociation of the biexciton must be faster than Auger recombination. It is important, then to have rapid charge transfer. Energy transfer of excitons can also reduce this problem of rapid Auger recombination because single excitons are longer lived in quantum-confined semiconductor materials than multiexcitons.

Rapid charge transfer (before Auger recombination loss of the multiexcitons that are produced by carrier multiplication) can be promoted by bringing an electron acceptor and/or hole donor into close proximity of the quantum-confined semiconductor material. The electron acceptor and/or hole donor materials can be the electrodes of the photovoltaic device or they can be small molecules or polymers that are mixed together with the quantum-confined material.

In order to increase the lifetime of multiexcitons, shape control of the quantum-confined material can be exploited to provide increased time for charge transfer and/or energy transfer (see for example Htoon et al. Phys. Rev. Lett. 2003, 91, 227401). Energy transfer such as described by Klimov et al. in U.S. patent application Ser. No. 10/843,737 entitled “Non-Contact Pumping of Light Emitters Via Non-Radiative Energy Transfer” may be used as well to separate multiexcitons into single excitons (electron-hole pairs) which have longer lifetimes and such description is hereby incorporated by reference.

This invention can be made use of by any means that generates highly excited carriers in a quantum-confined semiconductor material. This includes optical, electrical, or high-energy particle excitation of a quantum-confined semiconductor material.

Typical semiconductor devices such as photovoltaics (solar cells) operate via conversion of a single absorbed photon to a single electron hole pair, which is the source of current. Any photon energy that is in excess of the semiconductor band gap is typically wasted as heat, which lowers the power conversion efficiency of the device. Tandem cells are essentially stacks of several solar cells that have different semiconductor materials that absorb different photon energies and waste less of the photon energy as heat. Tandem cells have very high efficiencies of power conversion (34% has been demonstrated) but are also very expensive to construct because they involve many processing steps. Impact ionization-assisted solar cells would be much cheaper as they involve a minimal number of processing steps to construct, yet can provide high power conversion efficiencies. Also, tandem cells made of quantum-confined semiconductor materials can gain both the benefits of tandem cells as well as the benefits of carrier multiplication from absorption of high energy photons.

In one embodiment of the present invention, a photovoltaic cell is provided that employs an anode and a cathode with at least one of either the anode or cathode being transparent so as to allow the light or photons to contact a layer of quantum-confined semiconductor materials, e.g., semiconductor nanocrystals, disposed on one of either the anode or cathode. The layer of quantum-confined semiconductor materials, e.g., semiconductor nanocrystals, is capable of yielding carrier multiplication upon exposure to light of a sufficient energy level whereby greater than one electron-hole pair is generated per single absorbed photon from the light. The cell further can include a current collection element electrically connected to either the anode or cathode, so as to remove excitons (charge carriers or electron-hole pairs) from the cell.

Optical switches based on quantum-confined materials will benefit from this technology because optical switching is based upon the formation of excitons. The magnitude of a switching event is related to the number of excitons present. Thus, carrier multiplication can make a low fluence, high-energy excitation result in a large amplitude optical switching event.

Optical amplifiers based upon quantum-confined materials can benefit from carrier multiplication because lower excitation fluences of higher energy photons generate high-energy carriers that multiply, which assist in achieving population inversion.

The quantum confined materials in the present invention can be semiconductors or may be semiconductor-metal combinations. In one embodiment, the present invention uses quantum confined semiconductor materials, e.g., semiconductor nanocrystals. One suitable form of semiconductor nanocrystals can be colloidal semiconductor nanocrystals. Such semiconductor nanocrystals can be formed in situ through electrochemical or other reactive processes in addition to simply the addition or incorporation of colloidal nanocrystals.

Colloidal nanocrystals are generally members of a crystalline population having a narrow size distribution. The shape of the colloidal nanocrystals can be a sphere, a rod, a disk and the like. In one embodiment, the colloidal nanocrystals include a core of a binary semiconductor material, e.g., a core of the formula MX, where M can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In another embodiment, the colloidal nanocrystals include a core of a ternary semiconductor material, e.g., a core of the formula M₁M₂X, where M₁ and M₂ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In another embodiment, the colloidal nanocrystals include a core of a quaternary semiconductor material, e.g., a core of the formula M₁M₂M₃X, where M₁, M₂ and M₃ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TIP), thallium antimonide (TlSb), zinc cadmium selenide (ZnCdSe), mercury cadmium telluride (HgCdTe), mercury cadmium selenide (HgCdSe), mercury cadmium sulfide (HgCdS), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. In one embodiment, the colloidal nanocrystals are of silicon, germanium or alloys thereof. In another embodiment, colloidal nanocrystals can include a core of a metallic material such as gold (Au), silver (Ag), cobalt (Co), iron (Fe), nickel (Ni), copper (Cu), manganese (Mn), alloys thereof and alloy combinations with a shell of the desired quantum-confined semiconductor material. In another embodiment, colloidal nanocrystals may be of copper selenide (Cu₁₋₂Se), copper telluride (Cu₁₋₂Te) or copper sulfide (Cu₁₋₂S).

Additionally, the core of any semiconductor material or of any metallic material can have an overcoating on the surface of the core. The overcoating can also be a semiconductor material, such an overcoating having a composition different than the composition of the core. The overcoat on the surface of the colloidal nanocrystals can include materials selected from among Group II-VI compounds, Group II-V compounds, Group III-VI compounds, Group III-V compounds, Group IV-VI compounds, Group I-III-VI compounds, Group II-IV-V compounds, and Group II-IV-VI compounds. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), zinc cadmium selenide (ZnCdSe), mercury cadmium telluride (HgCdTe), mercury cadmium selenide (HgCdSe), mercury cadmium sulfide (HgCdS), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. The overcoating upon the core material can include a single shell or can include multiple shells for selective tuning of the properties. The multiple shells can be of differing materials. In addition to core/shell structures, the nanocrystals may have a fused dimer structure, a hetero-rod structure or a hetero-branched structure.

In one embodiment of the present invention, colloidal nanocrystals can be mixed with a suitable solid matrix precursor mixture, such as a lower alcohol, a non-polar solvent and a sol-gel precursor material, and the resultant solution used to form a solid composite. For example, the solution can be deposited onto a suitable substrate to yield homogeneous, solid composites from the solution of colloidal nanocrystals and sol-gel precursor. By homogeneous, it is meant that the colloidal nanocrystals are uniformly dispersed in the resultant product. In some instances, non-uniform dispersal of the colloidal nanocrystals is acceptable. In some embodiments of the invention, the solid composites can be transparent or optically clear. This first process of the present invention is a simple straight-forward process for preparing such solid composites.

Lower alcohols useful in this process can generally be an alcohol containing from one to four carbon atoms, i.e., a C₁ to C₄ alcohol. Among the suitable alcohols are included methanol, ethanol, n-propanol, isopropanol, n-butanol, sec-butanol and t-butanol.

Sol-gel processes generally refer to the preparation of a ceramic material by preparation of a sol, gelation of the sol and removal of the solvent. Sol-gel processes are advantageous because they are relatively low-cost procedures and are capable of coating long length conductors or irregularly shaped substrates. In forming the sol-gel based solution used in the processes of the present invention, suitable sol-gel precursor materials are mixed with the other components.

Sol-gel processes can be carried out as described by Brinker et al, “Sol-Gel Science, The Physics and Chemistry of Sol-Gel Processing”, Academic Press, 1990. Among suitable sol-gel precursor materials are included metal alkoxide compounds, metal halide compounds, metal hydroxide compounds, combinations thereof and the like where the metal is a cation from the group of silicon, titanium, zirconium, and aluminum. Other metal cations such as vanadium, iron, chromium, tin, tantalum and cerium may be used as well. Sol solutions can be spin-cast, dip-coated, or sprayed onto substrates in air. Sol solutions can also be cast into desired shapes by filling molds or cavities as well. Among the suitable metal alkoxide compounds can be included titanium tetrabutoxide (titanium(IV)butoxide), titanium tetraethoxide, titanium tetraisopropoxide, zirconium tetraisopropoxide, tetraethoxysilane (TEOS). Among suitable halide compounds can be included titanium tetrachloride, silicon tetrachloride, aluminum trichloride and the like.

For the processes of the present invention, the colloidal nanocrystals can include all types of nanocrystals capped with hydrophobic or hydrophilic ligands, including, e.g., semiconductor NQDs such as cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AIN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TIN), thallium phosphide (TIP), thallium antimonide (TlSb), lead sulfide (PbS), lead selenide (PbSe), lead telluride (PbTe), and mixtures of such materials.

Each of the present processes can provide resultant films that are optically transparent and hard. The colloidal nanocrystals are contained within a stable environment and the size dispersity of the colloidal nanocrystals within these materials is preserved. Of the present processes, the particular process employed can depend upon the ultimate application of interest. That is, for applications requiring high volume loadings or high refractive indices, the second process can be preferred, and for applications requiring simplicity or convenience, the first process can be preferred.

The present invention is more particularly described in the following example that is intended as illustrative only, since numerous modifications and variations will be apparent to those skilled in the art.

The PbSe, PbS and CdSe colloidal nanocrystals used in the examples were synthesized as previously described by Murray et al., J. Am. Chem. Soc., v. 113, 8706 (1993), by Dabbousi et al., J. Phys. Chem. B, v. 101, 9463 (1997), and by Qu et al., J. Am. Chem. Soc., v. 124, 2049 (2002).

### EXAMPLE 1

Time-resolved optical measurements were conducted in (semiconductor) lead selenide (PbSe) nanocrystals (NCs). Specifically, the technique of transient absorption was used to photo-excite and then optically monitor carrier population dynamics in oleic acid-passivated, PbSe nanocrystalline samples (size dispersity was about 5 to 10%) pump pulses 50 femtoseconds (fs) from an amplified Ti-sapphire laser (pump photon energies, ℏω=1.55 or 3.10 eV) or from a tunable optical parametric amplifier (OPA) excited NCs dissolved in hexane. The absorption change, Δα, within the photo-excited spot was probed with 100 fs pulses that were tuned via another OPA to band-edge (A₁) absorption maximum. As a measure of excitation density, an average number of photo-generated electron-hole pairs per nanocrystal, Nₑₕ, produced by the pump pulse were used to enable accurate calculation and experimental verification.

To observe that impact ionization was occurring, and to measure the efficiency of this process, the fact that when multiple carriers are present in a quantum-confined system, they can undergo rapid Auger recombination, which is a process that is opposite to impact ionization, was used. Auger recombination, thus, provided a dynamical signature of multiexciton formation via carrier multiplication.

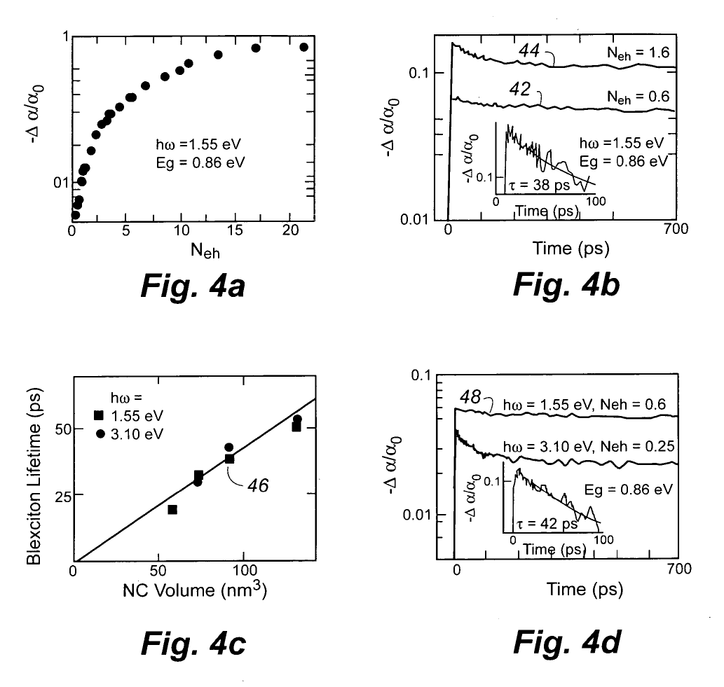

To measure characteristic decay constants of biexcitons, PbSe NC samples were first studied using 1.55 eV excitation for which impact ionization cannot occur (ℏω/E_{g}<2 for each sample). As a measure of NC populations, the normalized pump-induced bleaching of the lowest A₁ absorption maximum (−Δα/α₀; α₀ is the absorption coefficient of the unexcited sample) was used. As indicated in FIG. 4(a), absorption saturation measurements showed that Δα was almost linear with pump intensity up to Nₑₕ≈3 consistent with high 8-fold degeneracy of the lowest quantized states in PbSe. Therefore, Δα provided an accurate measure of Nₑₕ in both the single exciton and the biexciton excitation regimes examined. At low pump intensities, corresponding to the photogeneration of less than a single exciton per nanocrystal on average (Nₑₕ=0.6) (lower trace in FIG. 4(b)), a bleach of the A₁ absorption maximum was observed that relaxed slowly (on a much longer timescale than the utilized 2 ns delay stage could measure), consistent with a slow, radiative recombination of single excitons. As the pump intensity was increased to Nₑₕ=0.6 (upper trace in FIG. 4(b)), the bleach magnitude became larger and a faster relaxation component (on the picosecond timescale) appeared that was attributed to Auger recombination of biexcitons. A small portion of this “biexcitonic” component was also discernible at Nₑₕ=0.6 (lower trace in FIG. 4(b)), because, according to Poissonian statistics, there is also a finite probability to generate biexcitons, given by

$${P}_{2} = \frac{{N}_{eh}^{2}}{2} {ⅇ}^{- {N}_{eh}} ,$$

even at Nₑₕ<1. This fast component, measured using Nₑₕ=1.6, could be isolated from the single exciton dynamics and fit well to a single exponential decay (inset in FIG. 4(b)). The relaxation lifetimes measured for NCs of different sizes were found to be proportional to the NC volume (squares in FIG. 4(c)), as was previously observed for Auger recombination in CdSe NCs (see Klimov, Science 2000, 287, 1011). This result confirmed that the fast, pump intensity-dependent component originated from Auger recombination of biexcitons, which form as the result of absorption of two 1.55 eV photons by a NC.

Next, similar studies were performed on the same NC samples using 3.10 eV pump photons (FIG. 4(d)). For each of the studied NC samples, absorption of a 3.10 eV photon created an exciton that had more than 3 E_{g} (i.e., ℏωE_{g}>3) making impact ionization a possible relaxation route. Using low excitation intensities (Nₑₕ=0.25) (determined by taking into account the differences in absorption cross sections at the different photon excitation energies), A₁ band edge bleach dynamics were again measured. While at comparable excitation densities with 1.55 eV pump photon energy, the primary observation was slow “excitonic” dynamics (upper trace FIG. 4(d)), there was a clear observation of a large amplitude, fast component to the relaxation (lower trace in FIG. 4(d)) that is typical of biexciton dynamics. For all NC sizes studied with 3.10 eV excitation, this fast relaxation component decayed with the same rate as that of the “biexcitonic” decay from Auger recombination measured using the 1.55 eV pump photon energy (compare insets of FIGS. 4(b) and 4(d)). Furthermore, the fast relaxation time constant (circles in FIG. 4(c)) followed the same dependence on NC volume as that observed using 1.55 eV pump photon energy (squares in FIG. 4(c)), again indicative of Auger recombination. Further evidence that the detected biexcitons form due to impact ionization and not due to errors in pump intensity or absorption cross-section was apparent from the absolute magnitudes of changes in absorption (FIG. 4(d)).

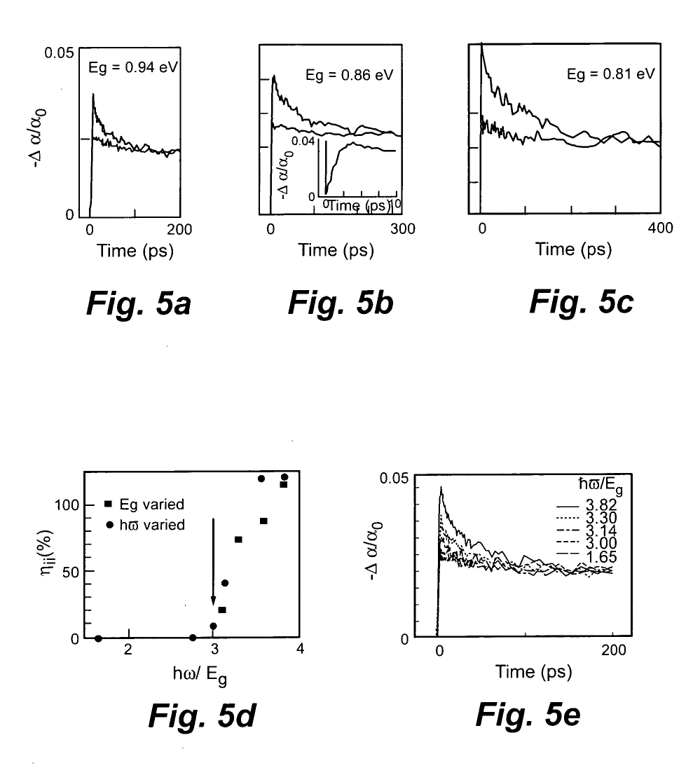

The efficiency of impact ionization was calculated in PbSe NCs using the procedure described in more detail in Schaller et al. Phys. Rev. Lett 2004, 92, 186601. As shown in FIGS. 5(a-c), for a fixed pump photon energy (3.10 eV), the efficiency of impact ionization increases as E_{g} decreases (FIG. 5(d)). As indicated in FIG. 5(d)), the threshold for impact ionization observed in these experiments was close to 3E_{g}. This observation can be explained by the “mirror” symmetry between the conduction and valence bands in the particular case of PbSe, i.e., the excess energy of the absorbed pump photon is partitioned approximately equally between the electron and hole of a photogenerated exciton. Therefore, the energy conservation requirement for impact ionization can only be satisfied if either an electron or hole has excess energy [approximately ℏω−E_{g}/2] of at least 1E_{g}. Studies performed using a pump pulse of tunable photon energy and a fixed NC E_{g} (FIG. 5(e)) showed a similar increase in impact ionization efficiency with excess energy as that observed for the case of a “variable” E_{g} (FIG. 5(d)). Efficiencies as high as 118% were observed for photon energies of 3.8 E_{g}. Such a high efficiency indicates that some of the absorbed photons produce not just biexcitons but triexcitons, meaning that in some NCs both the electron and the hole undergo impact ionization.

Despite the tens to hundreds of picosecond lifetime of biexcitons in PbSe NCs, the impact ionization-generated excitons will be useful for solar power generation. It has previously been demonstrated for different solar cell systems that the charge transfer step can be very fast (about 200 fs) and may occur with near unity efficiency. Therefore, Auger recombination should not compete with charge separation if the system is designed properly.

The theoretical treatment of Auger effects in NCs is extremely complex and therefore a theoretical picture of impact ionization in NCs has not been significantly developed. The conventional picture of impact ionization in bulk semiconductors is that exciton relaxation via impact ionization is competitive with intraband relaxation. A quantum mechanical picture of resonance between degenerate wave functions, in which either two (a single exciton) or four carriers (biexciton) exist, is also conceivable for NCs. Currently, while not wishing to be bound by the present explanation it is believed that the latter mechanism should produce a transient absorption signal that is essentially instantaneous, while the former should result in a delayed signal. Inspection of the transient absorption signal rise time shows that a measurable buildup time (with a picosecond rise time) exists for transient absorption signals that have a significant impact ionization component. Thus, impact ionization is very fast and competes with intraband relaxation in NCs, but does not appear to be an instantaneous process. Therefore, it is believed that the process occurs via the more conventional picture of impact ionization, in which impact ionization competes with intraband relaxation. This conclusion is also consistent with recent results on intraband relaxation, which show that intraband relaxation is slower than impact ionization, at least for the NC sizes studied here.

For a photovoltaic cell based on PbSe NCs of a single size, the NC E_{g} required to achieve maximum power conversion efficiency in the presence of impact ionization under concentrated solar illumination conditions can be estimated, assuming the internal quantum efficiency of the device to be 1. Shown in FIG. 4(a) are plots describing the effect of different impact ionization efficiencies for the case of 3E_{g} onset of the process. The optimal E_{g} shifts towards lower energy with increasing ηᵢᵢ and achieves a 10% increase in relative power conversion efficiency at ηᵢᵢ=100% in comparison to the efficiency of a cell without impact ionization (48.3% vs. 43.9%). Further improvement in power conversion efficiency can be achieved by reducing the threshold for impact ionization. Shown in FIG. 4(b) are the power conversion efficiencies as a function of material E_{g} for different onsets of impact ionization. A 37% increase in relative power conversion efficiency (to 60.3%) can be achieved via minimization of the impact ionization threshold to 2E_{g}, which should be realizable in NCs of materials that have significantly different carrier effective masses.

Many properties of PbSe NCs, including efficient impact ionization, lend themselves well to high efficiency solar cells. PbSe NCs have a broadly size-tunable E_{g} (about 0.3-1.3 eV) that facilitates the construction of tandem cells, and they absorb strongly from the ultraviolet to the near infrared. Moreover, functional solar cells based upon semiconductor NCs have been demonstrated. Finally, impact ionization is also likely to provide significant benefits with regard to other desirable properties of NCs such as reduced pump thresholds in NC-based optical amplifiers, lasers, and saturable absorbers as well as increased gain in avalanche photodiodes.

### EXAMPLE 2

Another study was done similar to Example 1 except that the laser light had a higher energy of 4.96 eV. Analysis showed that carrier multiplication had achieved between about 6 and 7 excitons per single absorbed photon.

### EXAMPLE 3

Another study was done similar to Example 1 except that the quantum dots were of PbS. Analysis showed that carrier multiplication had been achieved with about 4 excitons per single absorbed photon.

### EXAMPLE 4

Another study was done similar to Example 1 except that the quantum dots were of CdSe. Analysis showed that carrier multiplication had been achieved with about 2 excitons per single absorbed photon.

Although the present invention has been described with reference to specific details, it is not intended that such details should be regarded as limitations upon the scope of the invention, except as and to the extent that they are included in the accompanying claims.

What is claimed is:

1. A process of converting light into charge carriers comprising:
irradiating nanosized quantum confined semiconductor materials with light of sufficient energy to yield carrier multiplication whereby greater than one electron-hole pair is generated per single absorbed photon from said light.

2. The process of claim 1 wherein said carrier multiplication yields at least about 3 electron-hole pairs per single absorbed photon.

3. The process of claim 1 wherein said carrier multiplication yields at least about 6 electron-hole pairs per single absorbed photon.

4. The process of claim 1 wherein said semiconductor materials are selected from the group consisting of M₁X, M₁M₂X, and M₁M₂M₃X, where M₁, M₂, and M₃ are each selected from the group consisting of Zn, Cd, Hg, Al, Ga, In, Tl, Pb, Sn, Mg, Ca, Sr, Ba, mixtures and alloys thereof and X is selected from the group consisting of S, Se, Te, As, Sb, N, P and mixtures thereof, Si, Ge and alloys thereof.

5. The process of claim 1 wherein said semiconductor materials further include a core or shell of a metal selected from the group consisting of Au, Ag, Co, Fe, Ni, Cu, Mn and alloys of Au, Ag, Co, Fe, Ni, Cu, Mn or alloy combinations thereof.

6. The process of claim 1 wherein said semiconductor materials are selected from the group consisting of PbSe, PbS, CdSe, Si, Ge and alloys thereof.

7. The process of claim 1 wherein said nanosized quantum confined semiconductor materials are semiconductor nanocrystals.

8. The process of claim 1 wherein said nanosized quantum confined semiconductor materials are nanoporous materials.

9. The process of claim 8 wherein said nanoporous materials are porous silicon.

10. The process of claim 1 wherein said process further includes removing a portion of said electron-hole pairs prior to Auger recombination by said electron-hole pairs.

11. A process of converting a high energy charge carrier into additional charge carriers comprising:
contacting nanosized quantum confined semiconductor materials with high energy charge carriers to yield carrier multiplication whereby greater than one electron-hole pair is generated per single high energy carrier.

12. The process of claim 11 wherein said carrier multiplication yields at least about 3 electron-hole pairs per single high energy carrier.

13. The process of claim 11 wherein said carrier multiplication yields at least about 6 electron-hole pairs per single high energy carrier.

14. The process of claim 11 wherein said semiconductor materials are selected from the group consisting of M₁X, M₁M₂X, and M₁M₂M₃X, where M₁, M₂, and M₃ are each selected from the group consisting of Zn, Cd, Hg, Al, Ga, In, Ti, Pb, Sn, Mg, Ca, Sr, Ba, mixtures and alloys thereof and X is selected from the group consisting of S, Se, Te, As, Sb, N. P and mixtures thereof, Si, Ge and alloys thereof.

15. The process of claim 14 wherein said semiconductor materials further include a core or shell of a metal selected from the group consisting of Au, Ag, Co, Fe, Ni, Cu, Mn and alloys of Au, Ag, Co, Fe, Ni, Cu, Mn or alloy combinations thereof.

16. The process of claim 11 wherein said semiconductor materials are selected from the group consisting of PbSe, PbS, CdSe, Si, Ge and alloys thereof.

17. The process of claim 11 wherein said nanosized quantum confined semiconductor materials are semiconductor nanocrystals.

18. The process of claim 11 wherein said nanosized quantum confined semiconductor materials are nanoporous materials.

19. The process of claim 18 wherein said nanoporous materials are porous silicon.

20. The process of claim 11 wherein said process further includes removing a portion of said electron-hole pairs prior to Auger recombination by said electron-hole pairs.

21. A process of converting a high energy particle selected from the group of alpha particles, beta particles, gamma particles and x-rays into multiple charge carriers comprising:
contacting nanosized quantum confined semiconductor materials with a high energy particle selected from the group of alpha particles, beta particles, gamma particles and x-rays to yield carrier multiplication whereby greater than one electron-hole pair is generated per high energy particle.

22. The process of claim 21 wherein said carrier multiplication yield at least about 3 electron-hole pairs per high energy particle.

23. The process of claim 21 wherein said carrier multiplication yield at least about 6 electron-hole pairs per high energy particle.

24. The process of claim 21 wherein said semiconductor materials are selected from the group consisting of M₁X, M₁M₂X, and M₁M₂M₃X, where M₁, M₂, and M₃ are each selected from the group consisting of Zn, Cd, Hg, Al, Ga, In, Tl, Pb, Sn, Mg, Ca, Sr, Ba, mixtures and alloys thereof and X is selected from the group consisting of S, Se, Te, As, Sb, N, P and mixtures thereof, Si, Ge.

25. The process of claim 24 wherein said semiconductor materials further include a core or shell of a metal selected from the group consisting of Au, Ag, Co, Fe, Ni, Cu, Mn and alloys of Au, Ag, Co, Fe, Ni, Cu, Mn or alloy combinations thereof.

26. The process of claim 21 wherein said semiconductor materials are selected from the group consisting of PbSe, PbS, CdSe, Si, Ge and alloys thereof.

27. The process of claim 21 wherein said nanosized quantum confined semiconductor materials are semiconductor nanocrystals.

28. The process of claim 21 wherein said nanosized quantum confined semiconductor materials are nanoporous materials.

29. The process of claim 28 wherein said nanoporous materials are porous silicon.

30. A photovoltaic cell for converting light into charge carriers comprising:
an anode and a cathode wherein at least one of said anode and cathode is transparent;
a layer of semiconductor nanocrystals disposed on one of said anode and cathode, the layer of semiconductor nanocrystals capable of yielding carrier multiplication upon exposure to light of a sufficient energy level whereby greater than one electron-hole pair is generated per single absorbed photon from said light; and,
a current collection element wherein said current collection element is electrically connected to said anode or cathode, so as to remove charge carriers from the cell.

31. The photovoltaic cell of claim 30 wherein said semiconductor nanocrystals are colloidal nanocrystals.

32. The photovoltaic cell of claim 31 wherein said colloidal nanocrystals are in a sol-gel matrix.

33. The photovoltaic cell of claim 30 wherein said semiconductor nanocrystals are selected from the group consisting of M₁X, M₁M₂X, and M₁M₂M₃X, where M₁, M₂, and M₃ are each selected from the group consisting of Zn, Cd, Hg, Al, Ga, In, Tl, Pb, Sn, Mg, Ca, Sr, Ba, mixtures and alloys thereof and X is selected from the group consisting of S, Se, Te, As, Sb, N, P and mixtures thereof, Si, Ge, and alloys thereof.

34. The photovoltaic cell of claim 30 wherein said semiconductor nanocrystals are selected from the group consisting of PbSe, PbS, CdSe, Si, Ge and alloys thereof.

35. The photovoltaic cell of claim 30 further including a charge separation layer between said layer of semiconductor nanocrystals and either said anode or cathode.
